(19) United States
(12) Patent Application Publication
(10) Pub. No.: US 2016/0182001 A1
(43) Pub. Date: Jun. 23, 2016

(54) COMMON MODE NOISE FILTER

(71) Applicant: Hitachi, Ltd, Tokyo (JP)

(72) Inventors: Hua Zeng, Novi, MI (US); Yoshiyuki Tsuchie, Commerce Twp., MI (US); Masayoshi Takahashi, Yokohama (JP); Hiroki Funato, Chigasaki (JP)

(21) Appl. No.: 14/576,421

(22) Filed: Dec. 19, 2014

(51) Int. Cl. H03H 1/00

(52) U.S. Cl. CPC H03H 1/00; H03H 2001/0092

(57) ABSTRACT

A common mode noise filter adapted for connection in series between a noise source and a load having a first and second inductor connected in series respectively between the noise source and the load. A capacitor which exhibits stray inductance is connected in series with a third inductor having its other end connected to a junction of the first and second inductors. The first, second, and third inductors are selected and positioned relative to each other so that an absolute value of the third inductor and mutual inductance of the first, second, and third inductors minus the stray inductance of the capacitor is minimized.

### BACKGROUND OF THE INVENTION

I. Field of the Invention

The present invention relates generally to a common mode noise filter for an electrical system.

II. Description of Related Art

There are many previously known electrical systems which have a source of electrical noise. Unless the electrical noise is eliminated, or at least reduced, the electrical noise can adversely affect not only the operation of the electrical system itself, but also associated or nearby electrical systems.

For example, in an electric or hybrid automotive vehicle, a switching power supply or inverter is typically employed to generate the voltages needed to power the electric motors for the vehicle. Conventionally, switching field effect transistors (FET), GTO, or IGBT are used to create the power signal from the power supply. These FETs, however, generate a great deal of electrical noise each time the FETs switch between an on and off condition.

Such systems typically involve two different types of electrical noise which vary from each other in terms of their propagation path. First, there is differential mode current in which the current flows through two or more cables in the opposite direction to each other relative to the source and the load. Secondly, there is common mode current which flows through two or more cables in the same direction. This common mode current is typically high frequency and, of the two different types of electrical noise, is more troublesome than differential mode noise.

One previously known method of reducing common mode noise is to utilize a common mode filter electrically connected to the electrical system, preferably near the noise source. These previously known filters typically comprise a common mode choke coil L and a capacitor connected in between each power line of the electrical system and ground. The capacitors thus block any DC current from flowing through the capacitors and the common mode choke coil does not block any DC current, but act as a conductance path for high frequency common mode noise and as a block for high frequency common mode noise.

However, no capacitor exhibits the perfect properties of a capacitor. Instead, real life capacitors exhibit stray inductance (ESL) which decreases the overall efficiency of the common mode noise filter.

For example, see FIG. 1 in which the filter efficiency is plotted on the vertical axis while frequency is plotted on the horizontal axis. Assuming that the capacitor of the noise filter is a perfect capacitor without any stray inductance, the filter continuously reduces the amount of noise passing through the filter as the frequency of the noise increases as shown in graph 10. However, since no capacitor is perfect, graph 12 illustrates the lower efficiency of the filter when the stray inductance (ESL) of an actual capacitor is taken into account. As can be clearly seen from FIG. 1, the amount of common mode noise passing through the filter increases dramatically when the ESL is accounted for by graph 12.

There have been a number of previously known ways to decrease the ESL of the filter, and thus reduce the amount of common mode noise passing through the filter. For example, a decrease in the cable length of the cabling used to connect the filter to ground will decrease the amount of any stray inductance in the capacitor cables and thus reduce the ESL. For example, graph 14 in FIG. 1 illustrates the filter performance with shortened cable lengths for the capacitor against that of graph 12 in FIG. 1.

A still further method to reduce ESL is to use ESL cancelation. In ESL cancelation, each filter inductor of common mode filter is divided to two and those two inductors are coupled with each other and a negative inductance is shown up at the intermediate point of the two connected filter inductors. A capacitance can then be added between the intermediate point and ground. The inductor is ideally tuned to zero with a sum of ESL and the negative inductance. However, a conventional common mode LC filter with ESL cancelation uses a big common mode choke coil with much L. Then the negative inductance is also too much and need to add another coil in series with ESL of capacitance in order to tune the cancellation. Such cancellation circuits necessitate an increase in the overall number of parts, size, and weight of the noise filter. Furthermore, even if the inductance of the capacitor is a highly accurate inductor, the error of inductance can cause a large decrease in filter efficiency.

### SUMMARY OF THE PRESENT INVENTION

The present invention provides a common mode noise filter which overcomes the above mentioned disadvantages of the previously known noise filters.

In brief, the common mode noise filter of the present invention includes a first and a second inductor which are connected in series respectively between the noise source and the load. The inductance of the first inductor is much greater than the inductance of the second inductor.

A third inductor then has a first end connected to a junction between the first and second inductors. A second end of the third inductor is connected to one side of a capacitor which exhibits stray inductance (like all real capacitors) and the other side of the capacitor is connected to ground.

The first, second, and third inductors are selected and positioned relative to each other so that the mutual inductance M₁₃ between the first and third inductors prevents the negative inductance from becoming too small. The inductance L′=ESL+L₃−M₁₂−M₂₃+M₁₃. In effect, by minimizing the inductance L′ and ESL from the connection between the first and second inductors and ground, the overall efficiency of the common mode noise filter is enhanced thus more closely approximating the characteristics of an ideal filter illustrated by graph 10 in FIG. 1.

In one configuration, a wire is wound around a magnetic structure, such as a ring made up of a ferromagnetic material. A second wire is electrically connected to the first wire by a tap adjacent the load end of the wire and the second wire is then also wound around the magnetic structure and is then electrically connected to the load end. A third wire starts from the tap and goes around the magnetic structure along with the second wire. Then the third wire is connected to ground through a capacitor.

The length of wire between the noise source and the electrical tap on the wound, first wire, forms a first inductor L₁ while the length of wire from the tap around the magnetic structure to the load forms the second inductor L₂. The third inductor L₃ caused by the third wire, furthermore, is positioned closely adjacent the second inductor so that the second and third inductors are well coupled by mutual inductance.

All three inductors exhibit mutual inductance relative to each other. For example, M₁₂ is the mutual inductance between the first and second inductors, M₂₃ is the mutual inductance between the second and third inductors, and M₁₃ is the mutual inductance between the first and the third inductors. Each inductance is coupled with each other and the polarity is also shown in FIG. 3, where the polarity is described in dot conversion.

Consequently, the inductance of the path from the junction of the first and second inductors to the capacitor is equal to L₃−M₁₂−M₂₃+M₁₃ where L₃ is the magnitude of the third inductor. Ideally, this inductance is equal to the minus ESL for the capacitor thus more closely approximating an ideal filter. In general, L₁ and L₂ should be large in order to block high frequency current going between source and load and it also causes large M₁₂ and M₂₃. ESL usually is much smaller value than M₁₂ and M₂₃. However, L₃ and M₁₃ can prevent L₃−M₁₂−M₂₃+M₁₃ from being too small for ESL.

Although the filter of the present invention is particularly useful for use as a common mode noise filter, it may also be used as a differential mode noise filter with ESL cancellation if the one side of the common mode filter is just ground line.

### BRIEF DESCRIPTION OF THE DRAWING

A better understanding of the present invention will be had upon reference to the following detailed description when read in conjunction with the accompanying drawing, wherein like reference characters refer to like parts throughout the several views, and in which:

FIG. 1 is a graph depicting characteristics of an ideal filter and an actual filter;

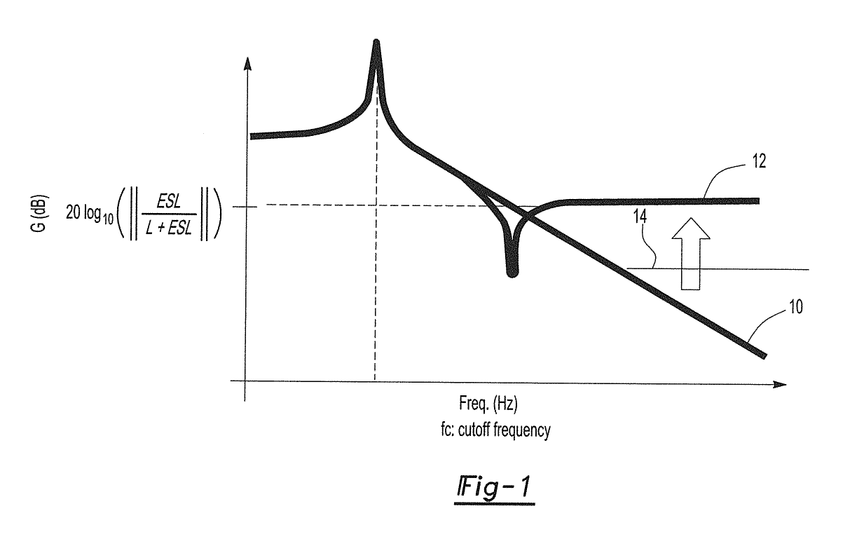

FIG. 2 is a side view and partial schematic view illustrating a preferred embodiment of the noise filter;

FIG. 3 is a schematic view illustrating circuit schematic of a noise filter;

FIG. 4 is an equivalent circuit of FIG. 3, where each voltage difference between terminals is equivalent to each other;

FIG. 5 is a perspective view illustrating structure of a noise filter; and

FIG. 6 is another perspective view illustrating structure of a noise filter with additional inductance to tune the total inductance to zero.

### DETAILED DESCRIPTION OF PREFERRED EMBODIMENTS OF THE PRESENT INVENTION

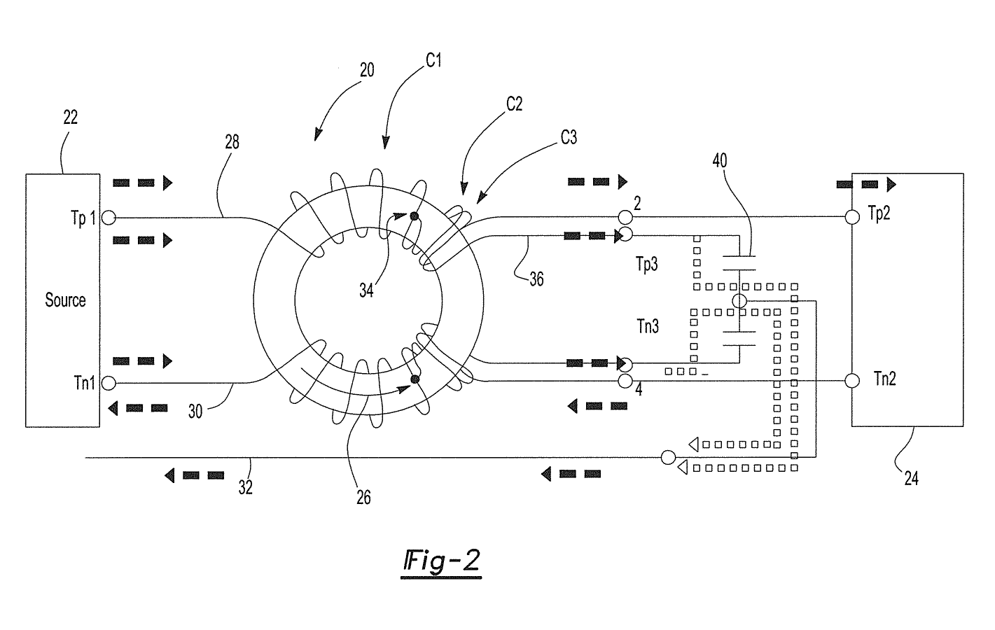

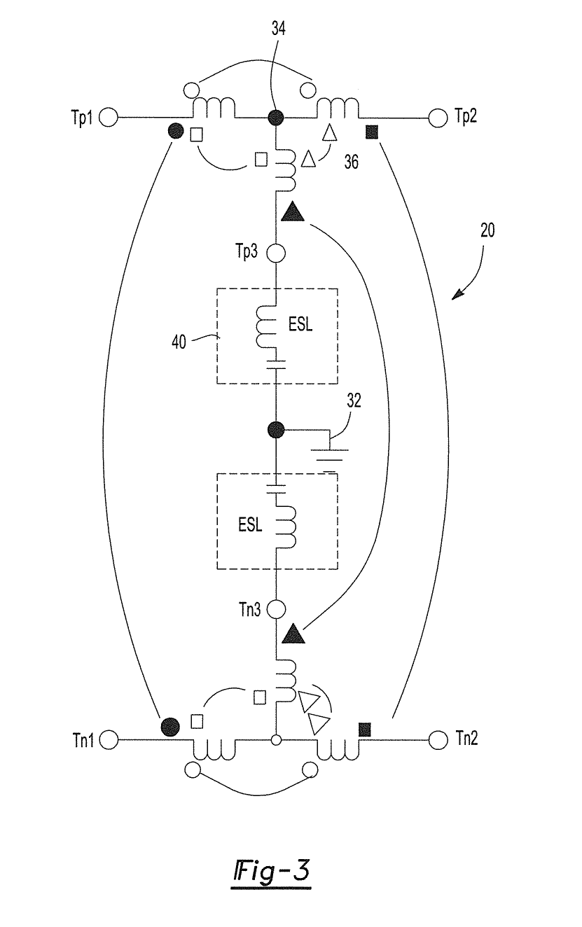

With reference first to FIGS. 2 and 3, a noise filter 20 is there shown interconnected between a source 22 of electrical noise, such as the inverter in a hybrid or electric motor vehicle, and a load 24, such as the battery of an electric or hybrid vehicle. The noise filter 20 is preferably positioned closely adjacent the source 22 of the electrical noise.

The noise filter 20 includes a magnetic structure 26, such as a ferrite bead. Wires 28 and 30 carry the common mode noise current from the noise source 22 to the load 24. A ground 32, such as a vehicle frame, is also associated with the noise filter 20.

Both the wires 28 and 30 between the noise source 22 and the load are wound around the magnetic structure 26. Furthermore, the two wires 28 and 30 are wound around the magnetic structure 26 in an identical fashion, and have identical components associated with them. Consequently, only the design and components associated with the wire 28 will be described in detail. An identical description shall also apply to the winding of the wire 30.

Still referring to FIGS. 2 and 3, the wire 28 extends from the noise source 22, is wound around the magnetic structure 26 a number of turns, and then connected to the load 24. A wire tap 34, however, is formed in the wire 28 at an intermediate point along the portion of the wire 28 wound around the magnetic structure 26. Furthermore, this tap 34 is positioned more closely to the load 24 than the source 22 of noise.

The tap 34 effectively divides the winding of the first wire 28 around the magnetic structure 26 into two inductors L₁ and L₂. The inductors L₁ and L₂ are connected in series with each other respectively between the noise source 22 and the load 24. Furthermore, the magnitude of the inductance of L₁ exceeds the inductance of the inductor L₂.

A second wire 36 is electrically connected to the junction point, tap 34, between the inductors L₁ and L₂. This wire 36 is wound around the magnetic structure 26 and forms a third inductor L₃. The third inductor L₃, furthermore, is positioned closely adjacent the second inductor L₂ thus increasing the mutual inductance between the inductors L₂ and L₃. Thus, the inductor L₃ is wound so that it is cancelled and causes a negative inductance relative to the inductance of the inductors L₁ and L₂.

The wire 26 is then connected to one side of a capacitor 40 and the other side of the capacitor 40 is electrically connected to ground 32. The capacitor 40, together with its attached wires 36 and connection to ground 32, exhibits stray inductance ESL. Ideally, the inductance L′−ESL=0 so that series inductance of the capacitance of the equivalent circuit from the tap 34 between the first inductor L₁ and second inductor L₂ and ground 32 and capacitor 40, is equal to zero in order to approximate an ideal noise filter.

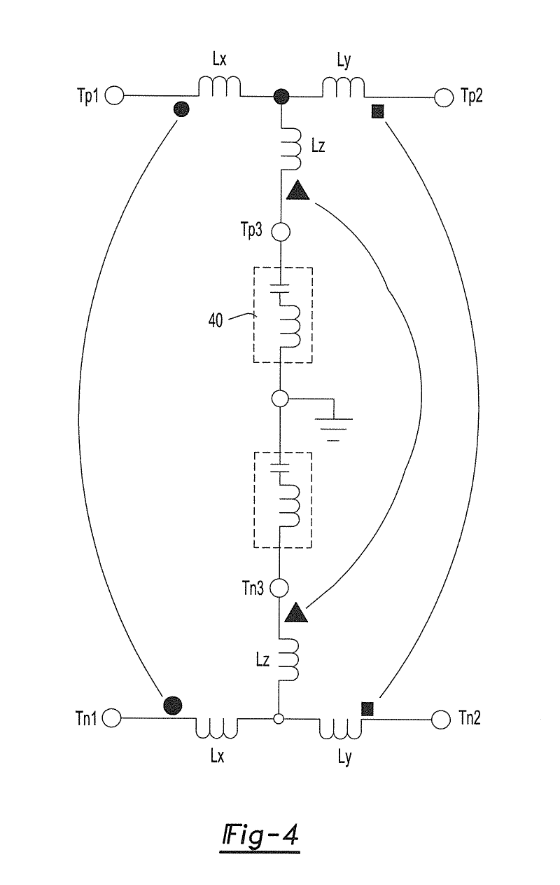

Each of the three inductors L₁, L₂, and L₃, however, is affected by the mutual inductance from the other two inductors. Consequently, assuming an equivalent circuit, three branches of equivalent inductance Lₓ, L_{y}, and L_{z} in FIG. 4. The values of the three branches of the filter Lₓ, L_{y}, and L_{z} are calculated as follows:

Lₓ=L₁+M₁₂+M₂₃+M_{13,}

L_{y}=L₂+M₁₂−M₂₃−M₁₃,

L_{z}=L₃−M₁₂−M₂₃+M₁₃,

where M is mutual inductance.

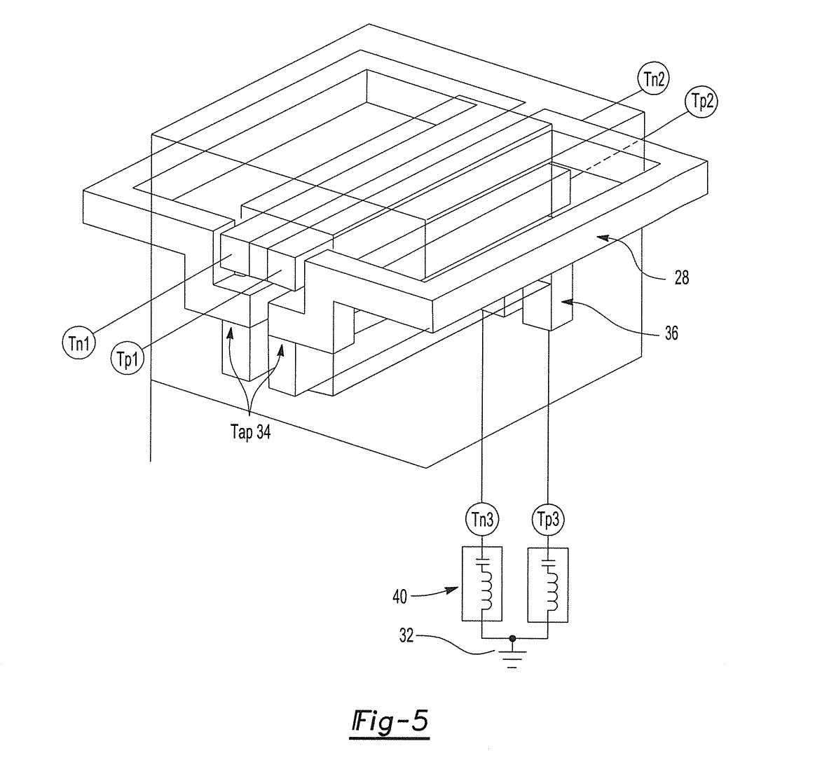

FIG. 5 also illustrates a design of FIG. 3. A wire 28 is wound around a ferrite block with one hole. A tap 34 is on the wire 28 at the side of a terminal Tₚ₁. A wire 36 goes into the hole of the ferrite block and is positioned close to the wire segment between the tap 34 and Tₚ₂ of wire 28. In this configuration, each polarity of mutual inductances matches that of FIG. 3.

Ideally, L_{z}−ESL equals 0. In actual applications, the filter may be tuned by adjusting the number of windings of the inductors L₁, L₂, and/or L₃ as well as by adjusting the mutual inductance M₁₂ between the inductors L₁ and L₂ by adjusting the length and width of the magnetic path of the inductors L₁ and L₂ on the magnetic structure 26.

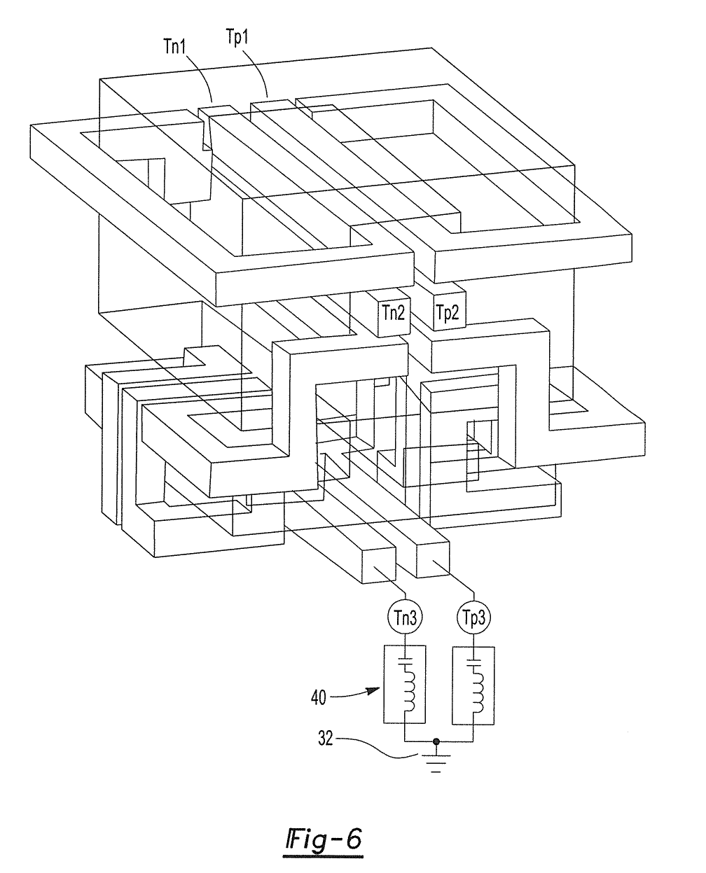

With reference now to FIG. 6, an alternative design for the three inductors L₁, L₂, and L₃ is shown. In each case, the inductors comprise a winding. FIG. 6 also illustrates a compensation inductor L_{c} which tunes L_{z} so that L_{z}+L_{c}−ESL=0. In FIG. 6, L_{c} has an orthogonal wounding axis against that of Lₓ, L_{y}, and L_{z}. So, even if L_{c} is close to the other inductors, the mutual inductance between L_{c} and the others gets smaller and independent of the other inductance. Thus, it's easy to choose the value of L_{c}.

From the foregoing, it can be seen that the present invention provides a simple yet highly effective common mode noise filter. Although the concept of the common mode noise filter may be used to decrease noise in differential mode electronic currents, it has proven highly effective in reducing common mode noise.

Having described our invention, however, many modifications thereto will become apparent to those skilled in the art to which it pertains without deviation from the spirit of the invention as defined by the scope of the appended claims.

We claim:

1. A common mode noise filter adapted for connection in series between a noise source and a load comprising:
a first and a second inductor connected in series respectively between the noise source and the load,
a capacitor which exhibits stray inductance,
a third inductor having a first end connected to a junction of said first and second inductors and a second end connected to one side of said capacitor, the other side of said capacitor connected to ground,
said first, second and third inductors selected and positioned relative to each other so that the difference between said capacitor stray inductance and the inductance of the third inductor less the mutual inductance between the first and second inductors and less the mutual inductance between the second and third inductors plus the mutual inductance between the first and third inductors is minimized.

2. The common mode noise filter as defined in claim 1 wherein said first, second and third inductors are wound on a common magnetic structure.

3. The common mode noise filter as defined in claim 2 wherein said magnetic structure comprises a ring.

4. The common mode noise filter as defined in claim 1 wherein said first, second and third inductors each comprise a winding on a magnetic structure.

5. The common mode noise filter as defined in claim 4 wherein said third inductor is wound closely adjacent said second inductor.

6. The common mode noise filter as defined in claim 1 wherein said first and second inductor comprise a winding on a magnetic structure and said first end of said third inductor comprises a tap at an intermediate point on said winding.

7. The common mode noise filter as defined in claim 1 wherein the value of said first inductor is greater than both said second and third inductors.

8. The common mode noise filter as defined in claim 1 wherein said first, second and third inductors each comprise a winding about an axis, and wherein the axis of an additional compensation inductor is perpendicular to the axes of said first, second, and third inductors.
